(19) United States
(12) Patent Application Publication
(10) Pub. No.: US 2020/0219959 A1
(43) Pub. Date: Jul. 9, 2020

(54) DISPLAY SUBSTRATE, METHOD FOR FABRICATING THE SAME, AND DISPLAY PANEL

(71) Applicant: BOE Technology Group Co., Ltd., Beijing (CN)

(72) Inventors: Jingang FANG, Beijing (CN); Luke DING, Beijing (CN); Bin ZHOU, Beijing (CN); Miao ZHANG, Beijing (CN)

(73) Assignee: BOE Technology Group Co., Ltd.

(21) Appl. No.: 16/711,667

(22) Filed: Dec. 12, 2019

(30) Foreign Application Priority Data
Jan. 3, 2019 (CN) 201910004898.2

(51) Int. Cl. H01L 27/32; H01L 51/52

(52) U.S. Cl. CPC H01L 27/3276; H01L 2251/303; H01L 27/3272; H01L 51/5237

(57) ABSTRACT

A display substrate, a method for fabricating the same, and a display panel are provided. The display substrate includes: a substrate, and a first conductive layer, at least two insulation layers, and a second conductive layer, the second conductive layer being electrically connected with the first conductive layer through via-holes, and the at least two insulation layers including a first insulation layer in contact with the first conductive layer, wherein the display substrate further includes an assisting alignment structure on the surface of the first insulation layer, and the orthographic projection of the assisting alignment structure surrounds at least part of the edge of the orthographic projection of the first via-hole in the first insulation layer on the substrate, so that the orthographic projection of the first via-hole on the first conductive layer lies within the pattern of the first conductive layer.

### CROSS-REFERENCES TO RELATED APPLICATION

This application claims priority to Chinese patent application No. 201910004898.2 filed on Jan. 3, 2019, which is incorporated herein by reference in its entirety.

### FIELD

The present disclosure relates to the field of display technologies, and particularly to a display substrate, a method for fabricating the same, and a display panel.

### BACKGROUND

An Organic Light-Emitting Diode (OLED) display panel has been increasingly applied to a smart display terminal as a next-generation display technology due to its high contrast, wide color gamut, high response speed, flexibility, and other advantages.

An OLED display panel with a large size and a high definition has gradually become an emerging focus, where a top gate of a transistor has been favored due to larger ON current, a high opening ratio, and higher stability thereof than a bottom gate. In order to enable the display panel to display an image at a higher resolution and a better visual effect, a smaller transistor size and a smaller line width, and also a smaller via-hole size in the display panel shall be made, so a via-hole shall be aligned with a signal line more precisely so that signal lines at different layers in the display panel can be electrically connected with each other stably through via-holes.

### SUMMARY

In an aspect, an embodiment of the disclosure provides a display substrate. The display substrate includes: a substrate, and a first conductive layer, at least two insulation layers, and a second conductive layer successively on the substrate in the direction away from the substrate, wherein the second conductive layer is electrically connected with the first conductive layer through via-hole penetrating through the at least two insulation layers, and the at least two insulation layers includes a first insulation layer in contact with the first conductive layer; and an assisting alignment structure on the surface of the first insulation layer away from the first conductive layer, an orthographic projection of the assisting alignment structure on the substrate surrounds at least part of an edge of an orthographic projection of first via-hole in the first insulation layer on the substrate, the assisting alignment structure has an opening at least corresponding to the first via-hole, and an orthographic projection of the opening on the first conductive layer lies within a pattern of the first conductive layer, so that an orthographic projection of the first via-hole on the first conductive layer lies within the pattern of the first conductive layer.

In some embodiments, the assisting alignment structure includes a third film layer, the third film layer includes a first part and a second part, an orthographic projection of the first part and an orthographic the second part on the substrate are are spaced apart at edges on two opposite sides of the orthographic projection of the first via-hole in the first insulation layer on the substrate, and the opening is a spacing area between the first part and the second part.

In some embodiments, the first conductive layer is a lead, and an arrangement direction of the first part and the second part is in an extension direction of the first conductive layer, or in a direction perpendicular to the extension direction of the first conductive layer.

In some embodiments, the assisting alignment structure includes a third film layer, an orthographic projection of the third film layer on the substrate surrounds the orthographic projection of the first via-hole on the substrate, and the opening is a second via-hole penetrating through the third film layer.

In some embodiments, a center axis of the first via-hole coincides with a center axis of the second via-hole.

In some embodiments, the diameter of the second via-hole is larger than or equal to the diameter of the first via-hole.

In some embodiments, the insulation layers further includes a second insulation layer on the side of the first insulation layer away from the first conductive layer; and a third via-hole penetrates through the second insulation layer, both center axis of the third via-hole and center axis of the second via-hole run through the third via-hole and the second via-hole, wherein the center axis of the third via-hole coincides with the center axis of the second via-hole, or the center axis of the third via-hole is offset from the center axis of the second via-hole.

In some embodiments, the diameter of the third via-hole is larger than or equal to the diameter of the second via-hole.

In some embodiments, the assisting alignment structure is made of a conductor or semiconductor material.

In some embodiments, the assisting alignment structure is made of a metal material or a metal oxide material, and the insulation layers are made of a silicon oxide or silicon nitride material.

In some embodiments, the sum of the thicknesses of the at least two insulation layers is more than 6000 angstroms.

In some embodiments, the width of the lead in the direction perpendicular to the extension direction thereof ranges from 0.2 μm to 0.5 μm.

In some embodiments, the display substrate further includes a light-shielding layer. The light-shielding layer is made of the same material and at the same layer as the first conductive layer, and the light-shielding layer is spaced from the first conductive layer.

In some embodiments, the display substrate further includes a transistor. The transistor includes an active layer, a gate insulation layer, a gate, and a source and a drain successively arranged in the direction away from the substrate, the source and the drain being at a same layer; the active layer is arranged on the side of the light-shielding layer away from the substrate in correspondence in position to the light-shielding layer, and the first insulation layer further extends to between the active layer and the light-shielding layer; and the assisting alignment structure is made of the same material, and is at the same layer as the active layer; and the second conductive layer is made of the same material and is at the same layer as the source and the drain, the second insulation layer further extends to between the active layer, and the source and the drain, and the second insulation layer further covers the gate and the gate insulation layer.

In some embodiments, the display substrate further includes: a pixel electrode on a side of the source and drain away from the substrate; and a third insulation layer between and the pixel electrode, and the source and drain; wherein the pixel electrode is electrically connected with the drain.

In another aspect, an embodiment of the disclosure further provides a display panel including the display panel above.

In another aspect, an embodiment of the disclosure provides a method for fabricating the display substrate above. The method includes: forming the first conductive layer on the substrate; forming the first insulation layer on the first conductive layer; forming the assisting alignment structure on the first insulation layer; forming at least one second insulation layer on the assisting alignment structure; forming via-holes in the second insulation layer and the first insulation layer; and forming the second conductive layer on the second insulation layer, where the second conductive layer is electrically connected with the first conductive layer through via-holes in the second insulation layer and the first insulation layer.

In some embodiments, in the method above, the assisting alignment structure, the first conductive layer, and the second conductive layer are formed through wet etching, and the first insulation layer, the second insulation layer and the via-holes in the first and second insulation layers are formed through dry etching.

### BRIEF DESCRIPTION OF THE DRAWINGS

FIG. 1 is a schematic structural diagram of a display substrate according to a first embodiment of the disclosure in a sectional view;

FIG. 2 is a schematic structural diagram of the display substrate in FIG. 1 in a sectional view along AA, where none of a first via-hole and a second via-hole is filled with a second conductive layer material;

FIG. 3 is another schematic structural diagram of the display substrate according to the first embodiment of the disclosure in a sectional view;

FIG. 4 is a schematic structural diagram of the display substrate in FIG. 1 in a sectional view along BB, where none of a first via-hole, a second via-hole, and a third via-hole is filled with a second conductive layer material;

FIG. 5 is a schematic structural diagram of a display substrate according to a second embodiment of the disclosure in a sectional view along AA in FIG. 1, where none of an opening, and a via-hole in a first insulation layer is filled with a second conductive layer material; and

FIG. 6 is another schematic structural diagram of the display substrate according to the second embodiment of the disclosure in a sectional view along AA in FIG. 1, where none of an opening, and a via-hole at a first insulation layer is filled with a second conductive layer material.

### DETAILED DESCRIPTION

Embodiments of the disclosure provide a display substrate, a method for fabricating the same, and a display panel. In the display substrate, the orthographic projection of the opening of the assisting alignment structure on the first conductive layer lies within a pattern of the first conductive layer, so that the orthographic projection of the first via-hole formed subsequently in the first insulation layer on the first conductive layer lies within the pattern of the first conductive layer, thus ensuring the precision of alignment between the first via-hole and the first conductive layer, and therefore the second conductive layer can be electrically connected with the first conductive layer stably through the via-holes in the respective insulation layers.

Further, the assisting alignment structure can protect the periphery of the first via-hole when the via-hole is formed subsequently by etching, to prevent the periphery of the first via-hole from being damaged.

In order to enable those skilled in the art to better understand the technical solutions according to the embodiments of the disclosure, a display substrate, a method for fabricating the same, and a display panel according to the embodiments of the disclosure will be described below in further details with reference to the drawings and particular implementations thereof

### First Embodiment

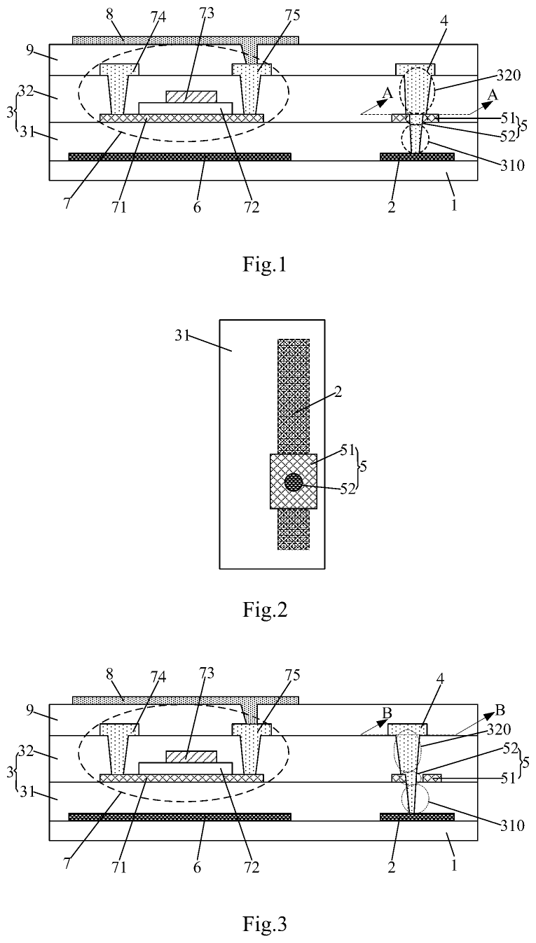

This embodiment provides a display substrate as illustrated in FIG. 1 and FIG. 2. The display substrate includes a substrate 1, and a first conductive layer 2, at least two insulation layers 3, and a second conductive layer 4 arranged successively on the substrate 1 in the direction away from the substrate 1, where the second conductive layer 4 is electrically connected with the first conductive layer 2 through the via-holes penetrating through at least two insulation layers 3, and the at least two insulation layers 3 include a first insulation layer 31 in contact with the first conductive layer 2; and the display substrate further includes an assisting alignment structure 5, the assisting alignment 5 is arranged on the surface of the first insulation layer 31 away from the first conductive layer 2, where the orthographic projection of the assisting alignment structure 5 on the substrate 1 surrounds at least part of edge of orthographic projection of first via-hole 310 in the first insulation layer 31 on the substrate 1, the assisting alignment structure 5 includes an opening at least corresponding to the first via-hole 310, and the orthographic projection of the opening on the first conductive layer 2 lies within the pattern of the first conductive layer 2, so that the orthographic projection of the first via-hole 310 on the first conductive layer 2 lies within the pattern of the first conductive layer 2.

The assisting alignment structure 5 is arranged on the surface of the first insulation layer 31 away from the first conductive layer 2, the opening of the assisting alignment structure 5 corresponds in position to the first via-hole 310 to be formed in the first insulation layer 31, and the opening of the assisting alignment structure 5 lies within the pattern range of the first conductive layer 2, which can ensure that the orthographic projection of the first via-hole to be formed in the first insulation layer 31 lies within the pattern of the first conductive layer 2, thus the precision of alignment between the first via-hole 310 and the first conductive layer 2 can be guaranteed. Further, the assisting alignment structure 5 can define the position where the first via-hole 310 to be formed, and even if there is some size or positional error of the subsequent via-hole in other insulation layer through etching, then the arranged assisting alignment structure 5 may well protect the precision position of the first via-hole 310 to be formed in the first insulation layer 31, thus avoiding improper connection of the first conductive layer 2, so that the second conductive layer 4 can be electrically connected with the first conductive layer 2 stably through the via-holes in all of the insulation layers.

In a possible implementation, the assisting alignment structure 5 includes a third film layer 51, where the orthographic projection of the third film layer 51 on the substrate 1 surrounds the orthographic projection of the first via-hole 310 on the substrate 1, and the opening of the assisting alignment structure 5 is a second via-hole 52 penetrating through the third film layer 51. Since the orthographic projection of the second via-hole 52 on the first conductive layer 2 fully lies within the pattern of the first conductive layer 2 at the position corresponding to the first via-hole 310 to be formed in the first insulation layer 31, so the assisting alignment structure 5 can ensure the orthographic projection of the first via-hole 310 on the first conductive layer lies within the pattern of the first conductive layer 2, thus ensuring the precision of alignment between the first via-hole 310 in the first insulation layer 31, and the first conductive layer 2. Further, the assisting alignment structure 5 can protect the periphery of the first via-hole 310 when the via-holes are formed subsequently in the first insulation layer 31 and other insulation layer, to prevent the periphery of the first via-hole from being damaged.

The center axis of the second via-hole 52 coincides with the center axis of the first via-hole 310. The diameter of the second via-hole 52 is larger than or equal to the diameter of the first via-hole 310. The insulation layers 3 further include a second insulation layer 32 arranged on the side of the first insulation layer 31 away from the first conductive layer 2, that is, there may be two insulation layers 3 in this embodiment. In this way, when the via-holes in the insulation layer 3 (including the first via-hole 310 in the first insulation layer 31 and the third via-hole 320 in the second insulation layer 32) are subsequently formed, the third film layer 51 in which the second via-hole 52 is formed can protect the periphery of the first via-hole 310 from being damaged. Meanwhile, the orthographic projection of the second via-hole 52 lies within the pattern of the first conductive layer, so as to guarantee precision alignment between the formed first via-hole 310 and the first conductive layer 2, so that the second conductive layer 4 can be electrically connected with the first conductive layer 2 stably through the first via-hole 310.

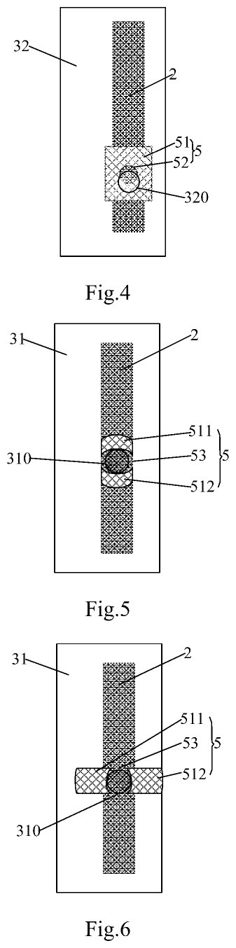

In this embodiment, the third via-hole 320 penetrates through the second insulation layer 32, both the center axis of the third via-hole 320 and the center axis of the second via-hole 52 run through the third via-hole 320 and the second via-hole 52, and the center axis of the third via-hole 320 coincides with the center axis of the second via-hole 52. It shall be noted that the center axis of the third via-hole 320 can alternatively be offset from the center axis of the second via-hole 52 as illustrated in FIG. 3 and FIG. 4. The diameter of the third via-hole 320 is larger than or equal to the diameter of the second via-hole 52. Since the assisting alignment structures 5 can protect the periphery of the first via-hole 310, no matter whether the center axis of the third via-hole 320 coincides with or is offset from the center axis of the second via-hole 52, the periphery of the first via-hole 310 can be avoided from being damaged when the third via-hole 320 and the first via-hole 310 are formed, so as to guarantee precision alignment between the first via-hole 310 and the first conductive layer 2, so that the second conductive layer 4 can be electrically connected with the first conductive layer 2 stably through third via-hole 320 and the first via-hole 310.

The assisting alignment structure 5 is made of a conductor or semiconductor material. The assisting alignment structure 5 of the conductor or semiconductor material can better protect the periphery of the first via-hole 310 in the first insulation layer 31 in contact with the first conductive layer 2 in a fabrication process than the structure of an insulation material.

Optionally, in this embodiment, the assisting alignment structure 5 is made of a metal material or a metal oxide material, and the insulation layers 3 are made of a silicon oxide or silicon nitride material. In a fabrication process, the assisting alignment structure 5 of the metal material or the metal oxide material is less likely to be damaged (e.g., in a subsequent dry etching process) than the insulation layers 3 of the silicon oxide or silicon nitride material, to thereby well protect the periphery of the first via-hole 310 in the first insulation layer 31, and ensure the precision of alignment between the first via-hole 310 and the first conductive layer 2.

It shall be noted that the assisting alignment structure 5 can alternatively be made of another conductor or semiconductor material, and the insulation layers 3 can alternatively be made of another insulation material; and since a layer of a conductor or semiconductor material in the display substrate is less likely to be damaged in a subsequent fabrication process than a layer of an insulation material in the display substrate, the periphery of the first via-hole 310 in the first insulation layer 31 can be well protected, and the precision of alignment between the first via-hole 310 and the first conductive layers 2 can be ensured.

Optionally the sum of the thicknesses of the at least two insulation layers 3 is more than 6000 angstroms, that is, in this embodiment, the sum of the thicknesses of the first insulation layer 31 and the second insulation layer 32 is more than 6000 angstroms. Since the two insulation layers 3 with a large thickness are typically etched twice to form the third via-hole 320 in the second insulation layer 32 and the first via-hole 310 in the first insulation layer 31, the periphery of the first via-hole 310 in the first insulation layer 31 is more likely to be damaged when the two via-holes in the insulation layers are formed through etching (e.g., due to over-etching) in this case, so the assisting alignment structure 5 can be arranged to well protect the periphery of the first via-hole 310 in the first insulation layer 31. the assisting alignment structure 5 can define the position where the first via-hole 310 to be formed, and even if there is some size or positional error of the subsequent via-hole in other insulation layer through etching, then the arranged assisting alignment structure 5 may well protect the precision position of the first via-hole 310 to be formed in the first insulation layer 31, thus avoiding improper connection of the first conductive layer 2, so that the second conductive layer 4 can be electrically connected with the first conductive layer 2 stably through the via-holes in the insulation layers.

It shall be further noted that when there is a small thickness of the two insulation layers 3, the via-holes in the two insulation layers 3 are typically formed in one etching process, and in this way, the assisting alignment structure 5 can define the position where the first via-hole 310 is formed when the via-holes in the two insulation layers 3 are formed, and even if there is some size or positional error of the third via-hole 320 in the second insulation layer 32, which is formed through etching, then the assisting alignment structure 5 may be arranged to well protect the periphery of the first via-hole 310 in the first insulation layer 31, so as to ensure the precision of alignment between the first via-hole 310 and the first conductive layers 2 so that the second conductive layer 4 can be electrically connected with the first conductive layer 2 reliably.

Optionally the shape of the orthographic projection of the second via-hole 52 on the first conductive layer 2 includes a round, an ellipse, a rectangle, or a regular hexagon. The via-hole in above shape can be formed precisely in a simple process. Of course, the shape of the orthographic projection of the second via-hole 52 on the first conductive layer 2 can alternatively be another regular polygon or irregular polygon.

In this embodiment, the display substrate further includes a light-shielding layer 6 and a transistor 7, where the light-shielding layer 6 is made of the same material as the first conductive layers 2, and arranged at the same layer as the first conductive layer 2, and the light-shielding layer 6 is spaced from the first conductive layer 2. The transistor 7 includes an active layer 71, a gate insulation layer 72, a gate 73, and a source 74 and a drain 75 at a same layer, arranged successively in the direction away from the substrate 1, where the active layer 71 is arranged on the side of the light-shielding layer 6 away from the substrate 1 in correspondence in position to the light-shielding layer 6, and the first insulation layer 31 further extends to between the active layer 71 and the light-shielding layer 6; and the assisting alignment structure 5 is made of the same material as the active layer 71, and arranged at the same layer as the active layer 71. The light-shielding layer 6 can shield light incident on the active layer 71 to thereby enhance ON current and the stability of the transistor 7. The second conductive layer 4 is made of the same material as the source 74 and the drain 75, and arranged at the same layer as the source 74 and the drain 75, the second insulation layer 32 further extends to between the active layer 71, and the source 74 and the drain 75, and the second insulation layer 32 further covers the gate 73 and the gate insulation layer 72. Stated otherwise, the assisting alignment structure 5 is arranged in the display substrate including transistor 7, and the assisting alignment structure 5 and the active layer 71 can be formed of the same material in the same patterning process without involving any additional process step of the display substrate.

Moreover the display substrate further includes a pixel electrode 8 arranged on the side of the source 74 and the drain 74 away from the substrate 1, and a third insulation layer 9 arranged between the pixel electrode 8, and the source 74 and the drain 75, where the pixel electrode 8 is electrically connected with the drain 75. In this embodiment, the display substrate can be a liquid crystal display substrate, or of course, the display substrate can alternatively be an organic light-emitting diode display panel.

In this embodiment, the first conductive layer 2 is a lead, where the width of the lead in the direction perpendicular to the extension direction thereof ranges from 0.2 μm to 0.5 μm. The lead can be a compensation signal line or a test signal line, but will not be limited thereto. The assisting alignment structure 5 can be arranged to ensure the precision of alignment between the third via-hole 320 and the first via-hole 310 to be below 0.5 μm, so as to greatly improve the precision of alignment between the via-holes in the insulation layers 3, and the thinner leads so that the second conductive layer 4 can be electrically connected with the first conductive layer 2 reliably.

It shall be noted that the insulation layers 3 between the first conductive layer 2 and the second conductive layer 4 can alternatively include more than three insulation layers.

It shall be further noted that the display substrate can include the assisting alignment structure 5 so that the via-hole in the insulation layers 3 in contact with the underlying lead can remain aligned precisely with the lead to thereby guarantee stable electrical connection between the thinner leads as long as the thinner leads at the different layers are electrically connected with each other through the via-hole in the more than two insulation layers, which are formed between the leads.

Further to the display substrate structured as described above, an embodiment of the disclosure further provides a method for fabricating the display substrate. The method includes:

Forming the first conductive layer 2 on the substrate 1;

Forming a first insulation layer 31 on the first conductive layer 2;

Forming the assisting alignment structure 5 on the first insulation layer 31, where the assisting alignment structure 5 is provided with an opening 52, the opening 52 corresponds to the first via-hole to be formed subsequently in the first insulation layer 31, and the orthographic projection of the opening 52 on the first conductive layer lies within the pattern of the first conductive layer 2;

Forming a second insulation layer 32 on the assisting alignment structure 5;

Forming via-holes 320, 310 in the second insulation layer 32 and the first insulation layer 31 by etching;

Forming the second conductive layer 4 on the second insulation layer 32, where the second conductive layer 4 is connected to the first conductive layer 1 through the via-holes 320, 310 in the second insulation layer and the first insulation layer.

The assisting alignment structure, the first conductive layer, and the second conductive layer are formed through wet etching, and the via-holes in the insulation layers are formed through dry etching.

Specifically, firstly the first insulation layer (6000 angstrom) is formed on the substrate, and the first insulation layer is made of a silicon oxide or silicon nitride. A metal layer or a metal oxide layer is formed on the first insulation layer and then is patterned by wet etching, to form the assisting alignment structure 5 with opening 52. In an implementation, the active layer 71 and the assisting alignment structure 5 with opening 52 can be formed in one patterning process. The etching liquid used in this wet etching is, for example, acid etching solution.

Thereafter, the second insulation layer 32 (4000 angstrom) is formed on assisting alignment structure 5 with the opening 52. After the second insulation layer 32 is formed, the via-holes 320, 310 in the second insulation layer 32 and the first insulation layer 31 are then formed by etching. The via-holes 320 and 310 are formed by dry etching, or wet etching using hydrofluoric acid etching solution and the like. During forming of the via-holes 310, 320 by etching, the etching is performed at least two twice and by controlling the etching time period and applying a certain-amount over-etching, to ensure the formed via-holes 320, 310 penetrate through the insulation layer (31, 32) to the first conductive layer 2.

After the via-holes 310, 320 are formed, the second conductive layer 4 is formed on the second insulation layer 32, the second conductive layer 4 is connected the first conductive layer 2 through via-holes 310, 320. The second conductive layer 4 and the source and drain layer are formed at the same layer and using the same patterning process.

In the embodiments of the disclosure, the opening of the assisting alignment structure 5 lies within the pattern range of the first conductive layer 2, which can ensure that the orthographic projection of the first via-hole to be formed in the first insulation layer 31 lies within the pattern of the first conductive layer 2, thus the precision of alignment between the first via-hole 310 and the first conductive layer 2 can be guaranteed. Further, after the assisting alignment structure 5 is formed, the assisting alignment structure 5 can protect the periphery of the first via-hole 310 when the via-holes are formed subsequently in the first insulation layer 31 and other insulation layer, to prevent the periphery of the first via-hole from being damaged.

It shall be noted that when the sum of the thicknesses of the at least two insulation layers is large, the via-holes in the insulation layers are typically formed in two or more etching processes. In this case, after the at least two insulation layers are formed, the via-holes in the insulation layers are formed in two or more etching processes, the periphery of the first via-hole in the first insulation layer may be damaged; or after the at least two insulation layers are formed, the via-holes in the insulation layers are formed in two or more etching processes, the first via-hole may be aligned with the first conductive layer less precisely due to a size or positional error. When the sum of the thicknesses of the at least two insulation layers is small, the via-holes in the at least two insulation layers are typically formed in one etching process, and in this case, the periphery of the first via-hole in the first insulation layer may be damaged when the via-holes are formed through etching. Accordingly the assisting alignment structure can be formed to well protect the periphery of the first via-hole in the first insulation layer so as to ensure the precision of alignment between the first via-hole and the first conductive layer, so that the second conductive layer can be electrically connected with the first conductive layer reliably.

In this method, the assisting alignment structure formed through wet etching will not be damaged when the insulation layers and the via-hole in the insulation layers is subsequently formed through dry etching, to thereby protect the periphery of the first via-hole in the first insulation layer in contact with the first conductive layer so as to guarantee precision alignment between the first via-hole in the first insulation layer and the first conductive layer, so that the second conductive layer can be electrically connected with the first conductive layer stably through the via-holes in the insulation layers.

The processes of forming the respective layers in the display substrate are well developed processes, so a repeated description thereof will be omitted here.

### Second Embodiment

This embodiment provides a display substrate, and as illustrated in FIG. 5 and FIG. 6, the display panel is different from the first embodiment in that the assisting alignment structure 5 includes the third film layer 51 including a first part 511 and a second part 512, where the orthographic projection of the first part 511 and the orthographic projection of the second part 512 on the substrate 1 are spaced apart at the edges on two opposite sides of the orthographic projection of the first via-hole 310 in the first insulation layer 31 on the substrate 1, and the opening is the spacing area between the first part 511 and the second part 512.

Since the opening 53 of the assisting alignment structure 5 corresponds in position to the first via-hole 310 in the first insulation layer 31, and the orthographic projection of the opening 53 of the assisting alignment structure 5 on the first conductive layer 2 completely lies within the pattern of the conductive layer, the assisting alignment structure 5 arranged at only a part of the edge of the first via-hole 310 in the first insulation layer 31 can also ensure the precision of alignment between the first via-hole 310 and the first conductive layer 2, and so as to guarantee the precision of alignment between the via-hole in the other insulation layer, and the first via-hole 310 in the first insulation layer 31, thus avoiding improper connection at the first conductive layer 2, so that the second conductive layer can be electrically connected with the first conductive layer 2 stably through the via-holes in the respective insulation layers.

The first conductive layer 2 is a lead, and the arrangement direction of the first part 511 and the second part 512 is in the extension direction of the first conductive layer 2 (as illustrated in FIG. 5), or in the direction perpendicular to the extension direction of the first conductive layer 2 (as illustrated in FIG. 6). The arrangement direction of the first part 511 and the second part 512 can vary with a different circuitry layout design.

The other structures of and a method for fabricating the display substrate in this embodiment will be the same as those in the first embodiment, so a repeated description thereof will be omitted here.

Advantageous effects of the first and second embodiments are as follows: in the display substrate according to the first and second embodiments, the assisting alignment structure is arranged on the surface of the first insulation layer in contact with the first conductive layer away from the first conductive layer, the opening of the assisting alignment structure corresponds in position to the first via-hole to be formed in the first insulation layer, the orthographic projection of the opening lies within the pattern of the first conductive layer, thus ensuring that the orthographic projection of the first via-hole to be formed in the first insulation layer lies within the pattern of the first conductive layer, so as to ensure the precision of alignment between the first via-hole and the first conductive layer, and avoid improper connection of the first conductive layer, so that the second conductive layer can be electrically connected with the first conductive layer stably through the via-holes in the insulation layers.

### Third Embodiment

This embodiment provides a display panel including the display substrate according to the first or second embodiment.

The quality of the display panel including the display substrate according to the first or second embodiment can be better guaranteed.

The display panel according to the embodiment of the disclosure can be an LCD panel, an LCD TV set, an OLED panel, an OLED TV set, a monitor, a mobile phone, a navigator, or any other product or component with a display function, or can be a self-finished product of the product or component above with the display function.

Advantageous effects of the disclosure are as follows: in the display substrate according to the disclosure the assisting alignment structure is arranged on the surface of the first insulation layer away from the first conductive layer, the opening of the assisting alignment structure corresponds in position to the first via-hole to be formed in the first insulation layer, and the opening of the assisting alignment structure lies within the pattern range of the first conductive layer, which can ensure that the orthographic projection of the first via-hole to be formed in the first insulation layer lies within the pattern of the first conductive layer, thus the precision of alignment between the first via-hole and the first conductive layer can be guaranteed. Further the second conductive layer can be electrically connected with the first conductive layer stably through the via-holes in the insulation layers. Further, when the via-holes in the at least two insulation layers are subsequently formed, the assisting alignment structure can protect the periphery of the first via-hole from being damaged.

The display panel according to the embodiment of the disclosure includes the display substrate above, so there will be a higher quality of the display panel.

As can be appreciated, the embodiments above are exemplary embodiments only intended to illustrate the principle of the disclosure, but the disclosure will not be limited thereto. Those ordinarily skilled in the art can make various modifications and variations thereto without departing from the spirit of the disclosure, and these modifications and variations shall also fall into the claimed scope of the disclosure.

1. A display substrate, comprising:
a substrate;
a first conductive layer, at least two insulation layers, and a second conductive layer successively on the substrate in a direction away from the substrate, wherein the second conductive layer is electrically connected with the first conductive layer through via-holes penetrating through the at least two insulation layers, and the at least two insulation layers comprise a first insulation layer in contact with the first conductive layer; and
an assisting alignment structure on a surface of the first insulation layer away from the first conductive layer, wherein an orthographic projection of the assisting alignment structure on the substrate surrounds at least part of an edge of an orthographic projection of a first via-hole in the first insulation layer on the substrate, the assisting alignment structure has an opening at least corresponding to the first via-hole, and an orthographic projection of the opening on the first conductive layer lies within a pattern of the first conductive layer, so that an orthographic projection of the first via-hole on the first conductive layer lies within the pattern of the first conductive layer.

2. The display substrate according to claim 1, wherein the assisting alignment structure comprises a third film layer, the third film layer comprises a first part and a second part, an orthographic projection of the first part and an orthographic projection of the second part on the substrate are spaced apart at edges of two opposite sides of the orthographic projection of the first via-hole in the first insulation layer on the substrate, and the opening is a spacing area between the first part and the second part.

3. The display substrate according to claim 2, wherein the first conductive layer is a lead, and an arrangement direction of the first part and the second part is in an extension direction of the first conductive layer, or in a direction perpendicular to the extension direction of the first conductive layer.

4. The display substrate according to claim 1, wherein the assisting alignment structure comprises a third film layer, an orthographic projection of the third film layer on the substrate surrounds the orthographic projection of the first via-hole on the substrate, and the opening is a second via-hole penetrating through the third film layer.

5. The display substrate according to claim 4, wherein a center axis of the first via-hole coincides with a center axis of the second via-hole.

6. The display substrate according to claim 5, wherein a diameter of the second via-hole is larger than or equal to a diameter of the first via-hole.

7. The display substrate according to claim 4, wherein the at least two insulation layers further comprise a second insulation layer on a side of the first insulation layer away from the first conductive layer; and
a third via-hole penetrates through the second insulation layer, both center axis of the third via-hole and center axis of the second via-hole run through the third via-hole and the second via-hole;
wherein the center axis of the third via-hole coincides with the center axis of the second via-hole, or the center axis of the third via-hole is offset from the center axis of the second via-hole.

8. The display substrate according to claim 7, wherein a diameter of the third via-hole is larger than or equal to a diameter of the second via-hole.

9. The display substrate according to claim 1, wherein the assisting alignment structure is made of a conductor or semiconductor material.

10. The display substrate according to claim 9, wherein the assisting alignment structure is made of a metal material or a metal oxide material, and the insulation layers are made of a silicon oxide or silicon nitride material.

11. The display substrate according to claim 1, wherein a sum of thicknesses of the at least two insulation layers is more than 6000 angstroms.

12. The display substrate according to claim 3, wherein a width of the lead in a direction perpendicular to an extension direction thereof ranges from 0.2 μm to 0.5 μm.

13. The display substrate according to claim 7, further comprising a light-shielding layer, wherein the light-shielding layer is made of a same material as the first conductive layer and is at a same layer as the first conductive layer, and the light-shielding layer is spaced from the first conductive layer.

14. The display substrate according to claim 13, further comprising a transistor, wherein the transistor comprises an active layer, a gate insulation layer, a gate, and a source and a drain successively in a direction away from the substrate, the source and the drain are at a same layer;
the active layer is on a side of the light-shielding layer away from the substrate in correspondence in position to the light-shielding layer, and the first insulation layer further extends to between the active layer and the light-shielding layer; and the assisting alignment structure is made of a same material as the active layer and is at a same layer as the active layer; and
the second conductive layer is made of a same material as the source and source, and is at a same layer as the source and the drain, the second insulation layer further extends to between the active layer and the source and the drain, and the second insulation layer further covers the gate and the gate insulation layer.

15. The display substrate according to claim 14, further comprising:
a pixel electrode on a side of the source and drain away from the substrate; and
a third insulation layer between the pixel electrode, and the source and drain; wherein the pixel electrode is electrically connected with the drain.

16. A display panel, comprising the display substrate according to claim 1.

17. A method for fabricating the display substrate according to claim 1, the method comprising:
forming the first conductive layer on the substrate;
forming the first insulation layer on the first conductive layer;
forming the assisting alignment structure on the first insulation layer;
forming at least one second insulation layer on the assisting alignment structure;
forming via-holes in the second insulation layer and the first insulation layer; and
forming the second conductive layer on the second insulation layer, wherein the second conductive layer is electrically connected with the first conductive layer through via-holes in the second insulation layer and the first insulation layer.

18. The method according to claim 17, wherein the assisting alignment structure, the first conductive layer, and the second conductive layer are formed through wet etching, and the via-holes in the first insulation layer and the second insulation layer are formed through dry etching.
